(19) United States
(12) Patent Application Publication
(10) Pub. No.: US 2026/0313244 A1
(43) Pub. Date: Oct. 8, 2026

(54) IMAGE SIGNAL PROCESSOR AND IMAGE SIGNAL PROCESSING METHOD

(71) Applicant: SK hynix Inc., Gyeonggi-do (KR)

(72) Inventors: Dong Ik KIM, Gyeonggi-do (KR); Jin Na YANG, Gyeonggi-do (KR); Cheol Jon JANG, Gyeonggi-do (KR); Jun Hyeok CHOI, Gyeonggi-do (KR)

(21) Appl. No.: 19/432,142

(22) Filed: Dec. 24, 2025

(30) Foreign Application Priority Data
Apr. 8, 2025 (KR) 10-2025-0045691

(51) Int. Cl. H04N 23/84; H04N 17/00; H04N 25/13; H04N 25/69; H04N 25/704

(52) U.S. Cl. CPC H04N 23/843; H04N 17/002; H04N 25/135; H04N 25/69; H04N 25/704

(57) ABSTRACT

An image signal processor includes a pixel data generator configured to generate first data by using pixel data of each of pixels having same attributes as a target pixel included in a target kernel from among a plurality of pixels included in the target kernel; a pixel group determiner configured to determine a correction pixel group from among a plurality of pixel groups included in the target kernel by using the first data; and a pixel interpolator configured to determine second data based on pixel data of pixels included in a pixel group including the target pixel and pixel data of pixels included in the correction pixel group and to determine pixel data of the target pixel based on the second data.

### CROSS-REFERENCE TO RELATED APPLICATION(S)

This present application claims priority to Korean patent application No. 10-2025-0045691, filed on Apr. 8, 2025, the entire disclosure of which is incorporated herein by reference.

### TECHNICAL FIELD

The present disclosure generally relates to an image signal processor capable of performing image conversion, and a method for processing an image signal.

### BACKGROUND

An image sensing device may capture optical images by converting light into electrical signals using a photosensitive semiconductor material which reacts to light. With the development of automotive, medical, computer and communication industries, the demand for high-performance image sensing devices is increasing in various devices such as smartphones, digital cameras, game machines, Internet of Things (IoT), robots, security cameras and medical micro cameras.

A pixel array that directly captures an optical image in an image sensing device may include defective pixels that cannot normally acquire a color image due to process errors. In order to implement an autofocus function, the demand for image sensing devices manufactured such that a pixel array includes phase difference detection pixel(s) is gradually increasing.

### SUMMARY

Various embodiments of the present disclosure relate to an image signal processor and an image signal processing method that may improve the accuracy of correction of defective pixels and the like.

Since a sensor that detects a phase difference inherently includes errors caused by the phase difference, defective pixels cannot be corrected using the existing general defective pixel correction algorithms. In order to address this issue, various embodiments of the present disclosure provide a defective pixel detection and correction method for correcting defective pixels in the sensor that detects a phase difference.

In accordance with an embodiment of the present disclosure, an image signal processor may include a pixel data generator configured to generate first data by using pixel data of each of pixels having same attributes as a target pixel included in a target kernel from among a plurality of pixels included in the target kernel; a pixel group determiner configured to determine a correction pixel group from among a plurality of pixel groups included in the target kernel by using the first data; and a pixel interpolator configured to determine second data based on pixel data of pixels included in a pixel group including the target pixel and pixel data of pixels included in the correction pixel group, and to determine pixel data of the target pixel based on the second data.

In accordance with another embodiment of the present disclosure, an image signal processor may include a pattern kernel determiner configured to determine whether a target kernel is a pattern kernel; a defective pixel determiner configured to determine whether a target pixel included in the target kernel is a defective pixel when it is determined that the target kernel is the pattern kernel; a pixel data generator configured to generate first data by using pixel data of pixels having same attributes as the target pixel when it is determined that the target pixel is the defective pixel; a pixel group determiner configured to determine a correction pixel group from among a plurality of pixel groups included in the target kernel by using the first data; and a pixel interpolator configured to determine second data based on pixel data of pixels included in a target pixel group including the target pixel and pixel data of pixels included in the correction pixel group, and to determine data of the target pixel based on the second data.

In accordance with another embodiment of the present disclosure, an image signal processing method may include: determining whether a target kernel including a target pixel is a pattern kernel; determining whether the target pixel is a defective pixel; generating first data by using pixel data of pixels having same attributes as the target pixel included in the target kernel; determining a correction pixel group from among a plurality of pixel groups included in the target kernel by using the first data; determining second data based on pixel data of pixels included in a target pixel group including the target pixel and pixel data of pixels included in the correction pixel group; and determining data of the target pixel based on the second data.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an image signal processor according to an embodiment of the present disclosure.

FIG. 2 is a detailed block diagram illustrating a defective pixel detector shown in FIG. 1 according to an embodiment of the present disclosure.

FIGS. 3A and 3B are block diagrams illustrating a defective pixel corrector shown in FIG. 1 according to an embodiment of the present disclosure.

FIG. 4 is a flowchart illustrating an operation of the image signal processor for use in a case where a target kernel is a pattern kernel according to an embodiment of the present disclosure.

FIG. 5 is a flowchart illustrating an operation of the image signal processor for use in a case where a target kernel is a flat kernel according to an embodiment of the present disclosure.

FIGS. 6 and 7 are diagrams illustrating examples in which operations S130 to S150 shown in FIG. 4 are performed according to an embodiment of the present disclosure.

FIG. 8 is a block diagram illustrating an example of a computing device corresponding to the image signal processor of FIG. 1 according to an embodiment of the present disclosure.

### DETAILED DESCRIPTION

The present disclosure provides implementations and examples of an image signal processor capable of performing image conversion, and a method for processing an image signal that may be used in configurations to substantially address one or more technical or engineering issues and to mitigate limitations or disadvantages encountered in some image signal processors in the art. Some implementations of the present disclosure relate to an image signal processor and an image signal processing method that may improve the accuracy of correction of defective pixels and the like. Since a sensor that detects a phase difference inherently includes errors caused by the phase difference, defective pixels cannot be corrected using the existing general defective pixel correction algorithms. In order to address this issue, some implementations of the present disclosure provide a defective pixel detection and correction method for correcting defective pixels in the sensor that detects a phase difference. In recognition of the issues above, the image signal processor and the image signal processing method according to the embodiments of the present disclosure may determine the directionality of a target kernel in consideration of characteristics of the sensor using a microlens, and may interpolate the target pixel based on the determined directionality, thereby providing a capability to improve the accuracy of defective pixel correction even when errors occur between pixels due to a phase difference.

Reference will now be made in detail to some embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

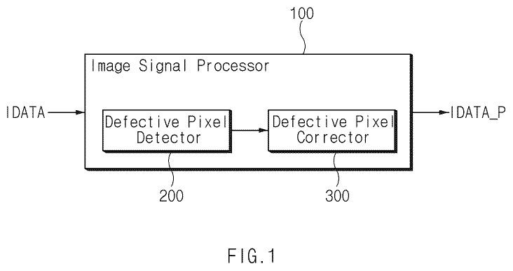

FIG. 1 is a block diagram illustrating an example of an image signal processor 100 according to embodiments of the present disclosure.

Referring to FIG. 1, the image signal processor (ISP) 100 may perform at least one image signal process on image data (IDATA) to generate the processed image data (IDATA_P). The ISP 100 may reduce noise of image data (IDATA), and may perform various kinds of image signal processing (e.g., demosaicing, defect pixel correction, gamma correction, color filter array interpolation, color matrix, color correction, color enhancement, lens distortion correction, etc.) for image-quality improvement of the image data. In addition, the ISP 100 may compress image data that has been created by execution of image signal processing for image-quality improvement, such that the ISP 100 may create an image file using the compressed image data. Alternatively, the ISP 100 may recover image data from the image file. In some embodiments, the scheme for compressing such image data may be a reversible format or an irreversible format. As a representative example of such compression format, in the case of using a still image, Joint Photographic Experts Group (JPEG) format, JPEG 2000 format, or the like may be used. In addition, in the case of using moving images, a plurality of frames may be compressed according to Moving Picture Experts Group (MPEG) standards such that moving image files may be created.

The image data (IDATA) may be generated by an image sensing device that captures an optical image of a scene, but the scope of the present disclosure is not limited thereto. The image sensing device may include a pixel array including a plurality of pixels configured to sense incident light received from a scene, a control circuit configured to control the pixel array, and a readout circuit configured to output digital image data (IDATA) by converting an analog pixel signal received from the pixel array into the digital image data (IDATA). In some embodiments of the present disclosure, it is assumed that the image data (IDATA) is generated by the image sensing device.

The pixel array of the image sensing device may include defective pixels that cannot normally capture a color image due to process limitations or temporary noise inflow. In addition, the pixel array may include phase difference detection pixels configured to acquire phase difference-related information to implement the autofocus function. The phase difference detection pixels cannot acquire color images in the same manner as normal pixels, such that the phase difference detection pixels may be treated as defective pixels from the point of view of color images. In some embodiments, for convenience of description and better understanding of the present disclosure, the defective pixel and the phase difference detection pixel, each of which cannot normally acquire the color image, will hereinafter be collectively referred to as “defective pixels.”

In order to increase the quality of color images, it is essential to improve the accuracy of correction of defective pixels. To this end, the image signal processor 100 according to some embodiments of the present disclosure may include a defective pixel detector 200 and a defective pixel corrector 300.

The defective pixel detector 200 may detect defective pixels based on the image data (IDATA). In one example, the defective pixel detector 200 may determine whether a target pixel, which is a subject of determination as to whether it is a defective pixel, is the defective pixel based on a difference between pixel data of the target pixel and pixel data of pixels within a kernel.

The defective pixel detector 200 may detect position information of defective pixels from the image data (IDATA). In one example, the defective pixel detector 200 may detect pixel data of the defective pixels. In the present disclosure, for simplicity, the digital data corresponding to the pixel signal of each pixel will be defined as pixel data, and a set of pixel data of pixels corresponding to a predetermined unit (e.g., frame or kernel) will be defined as image data (IDATA). Here, a frame corresponds to an entire pixel array, and a kernel may represent a unit for image signal processing. In the present disclosure, stating that pixels are “included” in a kernel may mean that the pixels “correspond” to a kernel corresponding to a specific operation unit.

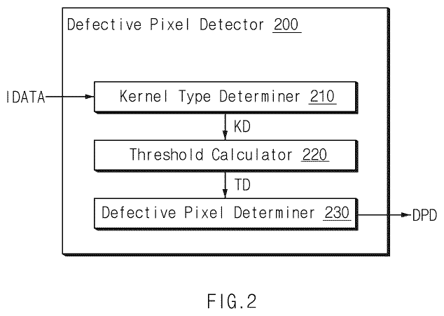

The defective pixel detector 200 may receive pre-stored position information about defective pixels from the image sensing device that generates image data (IDATA), and may determine whether the target pixel is a defective pixel based on the position information about the defective pixels. The image sensing device may store position information about fixed defective pixels in internal storage (e.g., one time programmable (OTP) memory) for process-related reasons and provide the position information about the defective pixels to the image signal processor 100. Operations of the defective pixel detector 200 will be described in further detail herein below with reference to FIG. 2.

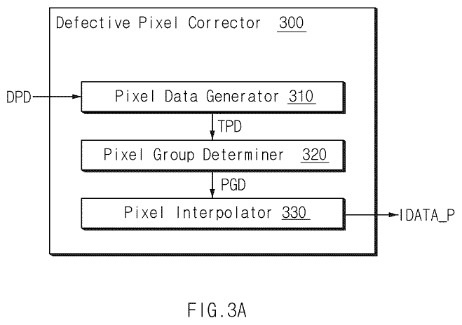

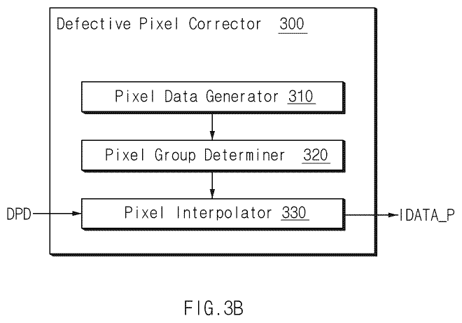

When the target pixel is determined to be a defective pixel by the defective pixel detector 200, the defective pixel corrector 300 may correct pixel data of a target pixel based on image data of a kernel including the target pixel. In one example, the defective pixel corrector 300 may correct the pixel data of the target pixel using pixel data of some pixels having the same attributes as the target pixel from among multiple pixels included in the kernel. More detailed operations of the defective pixel corrector 300 will be described herein below with reference to FIGS. 3A and 3B.

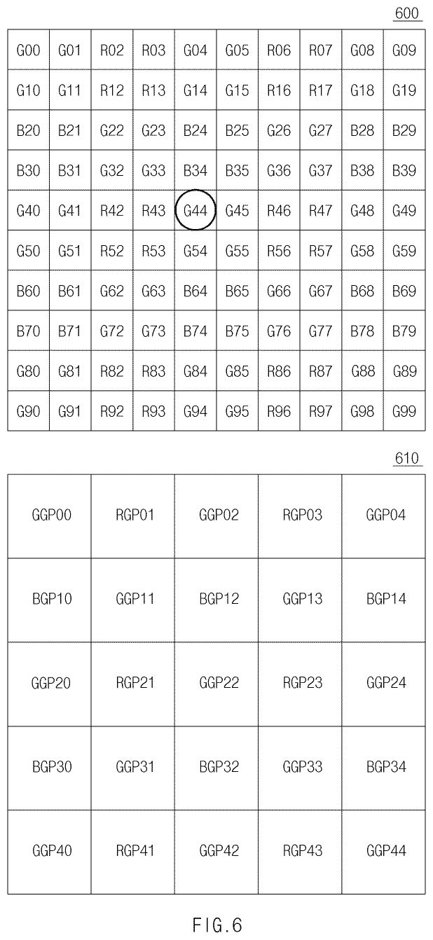

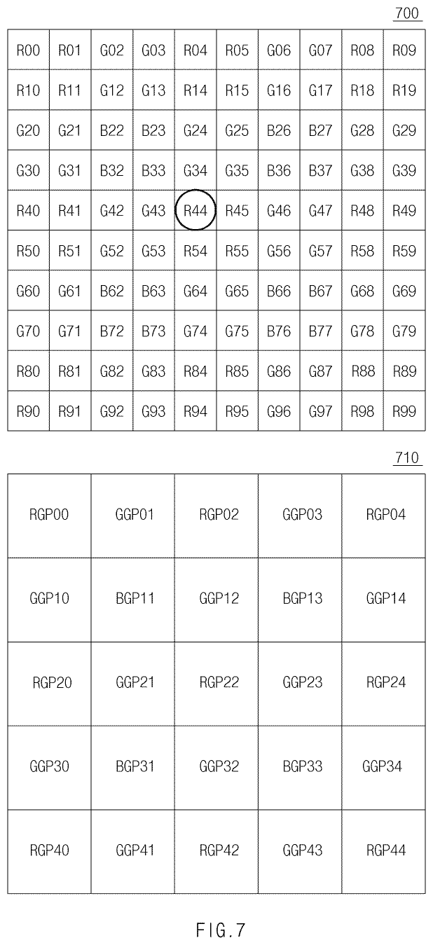

In the present disclosure, it is assumed that an all 4-coupled (A4C) type sensor is used. The A4C sensor may detect a phase difference while acquiring a color image from all pixels. The A4C sensor may include a configuration in which pixels arranged in a (2×2) matrix share a single microlens. A microlens array in this manner may be placed on top of a pixel array to focus incoming light onto the light-sensitive area of each pixel which allows balanced high-resolution imaging with good low-light performance. Specifically, the A4C sensor may be configured such that pixels arranged in a (2×2) matrix include color filters of the same color (which may be referred to as color filters). The A4C sensor may include unit pixel groups, each of which includes pixels arranged in a (4×4) matrix. In addition, the A 4C sensor may include a color filter array having a quad-Bayer pattern. Each of the unit pixel groups of the A4C sensor may correspond to a color filter array of the quad-Bayer pattern. Operations of the image signal processor 100 according to the present disclosure may be performed based on the image sensing operation of the A4C sensor. A detailed description of such pixel arrangement will be given herein below with reference to FIGS. 6 and 7.

FIG. 2 is a detailed block diagram illustrating the defective pixel detector 200 shown in FIG. 1 according to an embodiment of the present disclosure.

Referring to FIG. 2, the defective pixel detector 200 may include a kernel type determiner 210, a threshold calculator 220, and a defective pixel determiner 230.

The kernel type determiner 210 may receive image data (IDATA), and may determine whether a target kernel including a target pixel is a flat kernel or a pattern kernel. The target kernel may correspond to a target kernel for determining a flat kernel or a pattern kernel from among a set of pixel data of a predetermined unit including pixel data of the target pixel. In one example, the kernel type determiner 210 may be divided into a flat kernel determiner and a pattern kernel determiner.

A pattern kernel may correspond to a kernel that includes one or more textures. In one example, image data (IDATA) corresponding to a single frame may include textures of various sizes and shapes. The texture may refer to a set (or aggregate) of pixels having similarity. For example, a subject having a unified color included in a captured scene may be recognized as a texture. The boundary of the texture may include a corner, a stripe, and a grid, and a difference between pixel data inside the texture and pixel data outside the texture may appear larger than a typical difference between pixel data.

The kernel type determiner 210 may determine the target kernel to be a flat kernel when the target kernel does not correspond to a predetermined pattern type. For example, the kernel type determiner 210 may determine the target kernel to be a flat kernel when a standard deviation of pixel data of each pixel included in the target kernel is less than a set value. The set value may correspond to a value that is pre-stored in the image signal processor 100 to determine the type of a kernel. In one example, the kernel type determiner 210 may determine the target kernel to be a pattern kernel when the target kernel corresponds to a predetermined pattern type such as a corner pattern, a stripe pattern, or a grid pattern. For example, the kernel type determiner 210 may determine the target kernel to be a pattern kernel when the standard deviation of pixel data of each pixel included in the target kernel is equal to or greater than the set value.

The kernel type determiner 210 may transmit kernel type information (KD) of the target kernel to the threshold calculator 220. For example, the kernel type determiner 210 may transmit to the threshold calculator 220 the kernel type information (KD) indicating whether the target kernel has a flat kernel type or a pattern kernel type.

The threshold calculator 220 may receive the kernel type information (KD) and calculate a threshold serving as a reference value for detecting defective pixels. In one example, the threshold calculator 220 may calculate the threshold in different ways based on the kernel type of the target kernel.

When the target kernel is determined to be a flat kernel, the threshold calculator 220 may calculate a threshold based on the pixel data of pixels that correspond to a color filter of the same color as the target pixel and/or are located in the same channel as the target pixel. For example, the threshold calculator 220 may determine, as the threshold, a value corresponding to the standard deviation of the pixel data of pixels that correspond to the color filter of the same color as the target pixel and/or are located in the same channel as the target pixel. In the present disclosure, the pixels located in the same channel may refer to pixels having the same relative positions with respect to the center point of a microlens. A more detailed description of the pixels located in the same channel will be provided herein below with reference to FIGS. 6 and 7.

When the target kernel is determined to be a pattern kernel, the threshold calculator 220 may calculate a threshold based on the pixel data of pixels that are included in the same pattern as the target pixel, correspond to a color filter of the same color as the target pixel, and/or are located in the same channel as the target pixel. For example, when the target kernel is a corner pattern, the threshold calculator 220 may determine, as the threshold, a value corresponding to the standard deviation of the pixel data of pixels that are included in the same corner pattern as the target pixel, correspond to the color filter of the same color as the target pixel, and are located in the same channel as the target pixel.

The threshold calculator 220 may transmit threshold information (TD) including the calculated threshold to the defective pixel determiner 230. For example, the threshold calculator 220 may transmit, to the defective pixel determiner 230, the threshold information (TD) corresponding to the target kernel determined to be a flat kernel or the threshold information (TD) corresponding to the target kernel determined to be a pattern kernel.

In some embodiments, the threshold calculator 220 may determine the threshold as a fixed constant or as a specific ratio of a luminance value (e.g., green average value) of the current kernel. In one example, the threshold calculator 220 may determine (or set) the threshold based on the standard deviation of pixels located within the target kernel. For instance, the threshold calculator 220 may set a predetermined threshold by comparing the standard deviation of the pixel data of pixels located in the same channel within the target kernel with the standard deviation of the pixel data of pixels located in the target kernel.

The defective pixel determiner 230 may receive the threshold information (TD) and determine whether the target pixel is a defective pixel. In one example, the defective pixel determiner 230 may determine whether the target pixel is a defective pixel by comparing threshold value data (hereinafter referred to as threshold data) included in the threshold information (TD) with the pixel data of the target pixel. For instance, when a difference between the threshold data included in the threshold information (TD) and the pixel data of the target pixel is greater than or equal to a preset difference value, the defective pixel determiner 230 may determine the target pixel to be a defective pixel.

When the defective pixel determiner 230 determines the target pixel to be a defective pixel, the defective pixel determiner 230 may generate defective pixel information (DPD) including coordinate information of the target pixel and pixel data of the target pixel. In one example, the defective pixel information (DPD) may include information indicating whether the defective pixel is included in a target kernel determined to be a flat kernel or is included in a target kernel determined to be a pattern kernel.

FIGS. 3A and 3B are block diagrams illustrating the defective pixel corrector 300 shown in FIG. 1 according to an embodiment of the present disclosure.

Referring to FIG. 3A, the defective pixel corrector 300 may include a pixel data generator 310, a pixel group determiner 320, and a pixel interpolator 330.

The pixel data generator 310 may receive the defective pixel information (DPD) and calculate a temporary pixel data value for the target pixel determined to be a defective pixel. In one example, when the target kernel is a pattern kernel, the pixel data generator 310 may calculate the temporary pixel data value based on pixel data of pixels that are included in the same pattern as the target pixel, correspond to a color filter of the same color as the target pixel, and/or are located in the same channel as the target pixel.

When the target kernel is a pattern kernel, the pixel data generator 310 may calculate the temporary pixel data value using pixel data of some pixels that have the same attributes as the target pixel included in the target kernel from among all pixels included in the target kernel. For example, the pixel data generator 310 may calculate the temporary pixel data value using pixel data of one or more pixels that are located on a line in one direction from the target pixel and have the same attributes. In one example, the pixels having the same attributes as the target pixel may correspond to pixels that correspond to the same color filter as the target pixel and are located in the same channel.

The defective pixel corrector 300 may increase correction accuracy by performing calculations involved in the correction operation using the temporary pixel data value calculated by the pixel data generator 310, instead of directly using the pixel data of the target pixel determined to be a defective pixel. The pixel data generator 310 may transmit temporary pixel information (TPD) including the calculated temporary pixel data value to the pixel group determiner 320.

The pixel group determiner 320 may receive the temporary pixel information (TPD), and may determine a pixel group to be used to correct the target pixel by using the temporary pixel information (TPD). In one example, when the target kernel is a pattern kernel, the pixel group determiner 320 may determine, using the temporary pixel data, a correction pixel group among a plurality of pixel groups included in the target kernel.

When the target kernel is a pattern kernel, the pixel group determiner 320 may determine, among the pixel groups included in the target kernel, the pixel group most similar to the target pixel group that includes the target pixel. For example, the pixel group determiner 320 may determine a correction pixel group based on a comparison result between the temporary pixel data and the pixel data of some pixels having the same attributes as the target pixel from among pixels included in the plurality of pixel groups. For instance, the pixel group determiner 320 may determine the correction pixel group based further on a comparison result between pixel data of an adjacent pixel neighboring the target pixel and pixel data of some pixels having the same attributes as the adjacent pixel from among pixels included in the plurality of pixel groups. In one example, a pixel (i.e., an adjacent pixel) neighboring a certain pixel may correspond to a pixel whose center is located at a distance less than two pixel pitches from the center of a specific pixel. In another example, a pixel adjacent to the specific pixel may correspond to a pixel that shares a microlens with the specific pixel.

The defective pixel corrector 300 may increase correction accuracy even in a target kernel having a complex pattern by performing a correction operation using pixels included in a correction pixel group. For example, even when the target kernel is a kernel having a complex pattern in which multiple patterns are mixed, the correction accuracy may be increased by using a correction pixel group composed of pixels similar to the target pixel. The pixel group determiner 320 may provide pixel group information (PGD), including positions and pixel data information of the pixels included in the correction pixel group, to the pixel interpolator 330. Details of the process for determining the correction pixel group are provided herein below with reference to FIGS. 6 and 7.

The pixel interpolator 330 may receive the pixel group information (PGD). The pixel group information (PGD) may include pixel data of pixels included in the correction pixel group. The pixel interpolator 330 may interpolate pixel data of the target pixel using the pixel data of the pixels included in the correction pixel group. In one example, when the target kernel is a pattern kernel, the pixel interpolator 330 may interpolate the pixel data of the target pixel by comparing the pixel data of pixels included in the pixel group containing the target pixel with the pixel data of pixels included in the correction pixel group.

The pixel interpolator 330 may interpolate the pixel data of the target pixel using the pixel data of the pixels included in the correction pixel group. In one example, the pixel interpolator 330 may interpolate the pixel data of the target pixel based on the pixel data of pixels included in the correction pixel group that have the same attributes as the target pixel. In addition, the pixel interpolator 330 may further interpolate the pixel data of the target pixel based on a comparison result between the pixel data of an adjacent pixel neighboring the target pixel and the pixel data of some pixels having the same attributes as the adjacent pixel from among pixels included in the correction pixel group. In some embodiments, the pixel interpolator 330 may determine, as the pixel data of the target pixel, an average value of the pixel data of some pixels having the same attributes as the adjacent pixel from among pixels included in the correction pixel group.

The pixel interpolator 330 may interpolate the pixel data of the target pixel to generate corrected image data (IDATA_P). A detailed description of the process of interpolating the pixel data is provided herein below with reference to FIGS. 6 and 7.

Referring to FIG. 3B, the defective pixel corrector 300 may include a pixel data generator 310, a pixel group determiner 320, and a pixel interpolator 330. In one example, when the target kernel is a flat kernel, the defective pixel corrector 300 may deactivate the pixel data generator 310 and the pixel group determiner 320, and may activate the pixel interpolator 330.

When the target kernel is a flat kernel, the pixel interpolator 330 may receive the defective pixel information (DPD) and may calculate the pixel data value of the target pixel determined to be a defective pixel. In one example, referring also to FIG. 2, when the target kernel is a pattern kernel, the defective pixel determiner 230 may transmit the defective pixel information (DPD) to the pixel data generator 310 as shown in FIG. 3A, and when the target kernel is a flat kernel, the defective pixel determiner 230 may transmit the defective pixel information (DPD) to the pixel interpolator 330 as shown in FIG. 3B.

When the target kernel is a flat kernel, the pixel interpolator 330 may calculate the pixel data value of the target pixel by using pixel data of some pixels having the same attributes as the target pixel from among pixels included in the target kernel. In one example, the pixels having the same attributes as the target pixel may correspond to pixels that correspond to the same color filter as the target pixel and are located in the same channel as the target pixel.

The pixel interpolator 330 may determine, as the pixel data of the target pixel, an average of the pixel data of some pixels having the same attributes as the target pixel from among pixels included in the target kernel. In one example, when the target kernel is a flat kernel, the pixel interpolator 330 may interpolate the pixel data of the target pixel based on a comparison result between the pixel data of an adjacent pixel neighboring the target pixel and the pixel data of some pixels having the same attributes as the adjacent pixel from among pixels included in the target kernel.

The pixel interpolator 330 may interpolate the pixel data of the target pixel to generate corrected image data (IDATA_P). A detailed description of the process of interpolating the pixel data is provided herein below with reference to FIGS. 6 and 7.

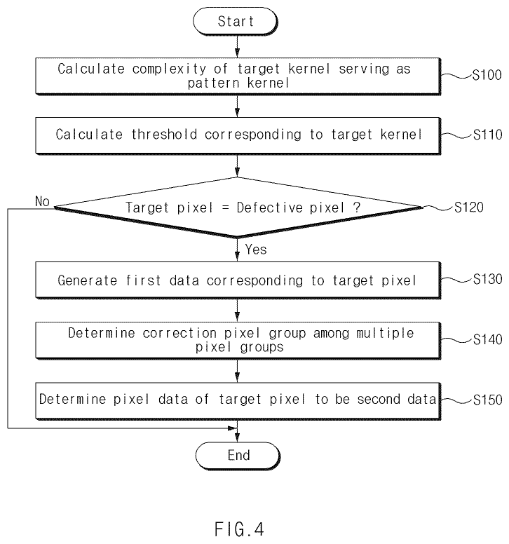

FIG. 4 is a flowchart illustrating an operation of the image signal processor (ISP) for use in a case where the target kernel is a pattern kernel according to an embodiment of the present disclosure.

Referring to FIGS. 2, 3A, and 4, when the target kernel is determined to be a pattern kernel by the kernel type determiner 210, the threshold calculator 220 may calculate the complexity of the target kernel serving as the pattern kernel (Operation S100). For example, the threshold calculator 220 may determine, as the complexity of the target kernel, the standard deviation of the pixel data of pixels that are included in the same pattern as the target pixel and correspond to the same color and the same channel as the target pixel.

The threshold calculator 220 may calculate the complexity of the target kernel, and may use the calculated complexity for threshold calculation. For example, when the condition for determining the target pixel to be a defective pixel is that a difference between the pixel data of the target pixel and an average of the pixel data of surrounding pixels exceeds a threshold, as the complexity of the target kernel increases, the threshold may also increase.

The threshold calculator 220 may calculate a threshold corresponding to the target kernel based on the complexity of the target kernel (Operation S110). The size of the threshold may be determined relative to the complexity of the target kernel. For example, the threshold calculator 220 may set the threshold to a value of 10 when the complexity of the target kernel is 5, and may set the threshold to a value of 20 when the complexity of the target kernel is 10. In one example, when the target kernel is determined to be a pattern kernel, the threshold calculator 220 may calculate a threshold based on the pixel data of pixels that are included in the same pattern as the target pixel and correspond to the same color and the same channel as the target pixel.

The defective pixel determiner 230 may determine whether the target pixel is a defective pixel based on the threshold (Operation S120). The defective pixel determiner 230 may determine the target pixel to be a defective pixel when a difference between the pixel data of the target pixel and an average of the pixel data of surrounding pixels exceeds the threshold. For example, when the target pixel is included in a pattern region, the defective pixel determiner 230 may determine the target pixel to be a defective pixel when a difference between the pixel data of the target pixel and an average of the pixel data of pixels that are included in the same pattern as the target pixel and correspond to the same color and the same channel as the target pixel exceeds the threshold.

When it is determined that the target pixel is not a defective pixel as a result of determining whether the target pixel is a defective pixel (No in S120), the image signal processor 100 may determine that no separate defective pixel correction is required and may terminate the process.

When it is determined that the target pixel is a defective pixel as a result of determining whether the target pixel is a defective pixel (Yes in S120), the pixel data generator 310 may generate first data corresponding to the target pixel (Operation S130). The first data may correspond to temporary pixel data, which is a temporarily corrected value of the pixel data of the defective pixel.

In some embodiments, the pixel data generator 310 may determine the directionality of the target kernel, and may calculate a temporary pixel data value based on the pixel data of pixels that are included in the same direction as the target pixel and correspond to the same color and the same channel as the target pixel. For example, when the target kernel has a horizontal stripe pattern, the pixel data generator 310 may calculate first data based on pixel data of pixels that are located to the left or right side of the target pixel and correspond to the same color and the same channel as the target pixel.

The pixel group determiner 320 may determine, among a plurality of pixel groups included in the target kernel, a correction pixel group based on the first data (Operation S140). The pixel group determiner 320 may compare the first data, which is temporary pixel data of the target pixel, with the pixel data of other pixels, and may determine the correction pixel group most suitable for correcting the target pixel.

For example, the pixel group determiner 320 may determine, as the correction pixel group, the pixel group corresponding to the smallest difference value obtained by comparing the first data with the pixel data of some pixels having the same attributes as the target pixel from among pixels included in the plurality of pixel groups. For instance, the pixel group determiner 320 may additionally compare the pixel data of an adjacent pixel neighboring the target pixel with the pixel data of pixels having the same attributes as the adjacent pixel from among pixels included in the plurality of pixel groups, and may determine, as the correction pixel group, the pixel group corresponding to the smallest difference value.

The pixel interpolator 330 may determine the pixel data of the target pixel as second data by using the pixel data of pixels included in the correction pixel group (Operation S150). In one example, the pixel interpolator 330 may determine the second data based on pixel data of an adjacent pixel neighboring the target pixel, pixel data of some pixels having the same attributes as the target pixel from among pixels included in the correction pixel group, and pixel data of some pixels having the same attributes as the adjacent pixel.

For example, the pixel interpolator 330 may determine, as the second data, a sum value obtained by summing pixel data of an adjacent pixel neighboring the target pixel, an average of differences between pixel data of some pixels having the same attributes as the adjacent pixel from among pixels included in the correction pixel group, and pixel data of some pixels having the same attributes as the target pixel.

The pixel interpolator 330 may perform an interpolation operation for the target pixel by converting the first data, which is temporarily set for the pixel data of the target pixel, into the second data. The pixel interpolator 330 may generate corrected image data (IDATA_P) including the interpolated pixel data of the target pixel.

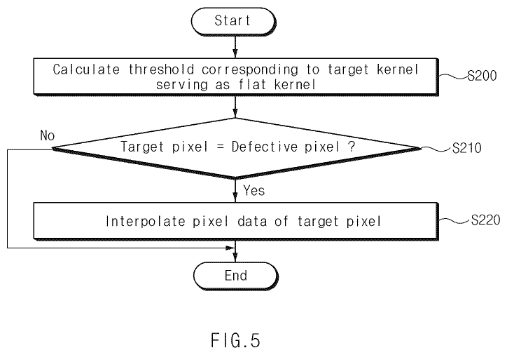

FIG. 5 is a flowchart illustrating an operation of the image signal processor for use in a case where a target kernel is a flat kernel according to an embodiment of the present disclosure.

Referring to FIGS. 2, 3B, and 5, when the target kernel is determined to be a flat kernel by the kernel type determiner 210, the threshold calculator 220 may calculate a threshold corresponding to the target kernel (Operation S200). In one example, the threshold calculator 220 may calculate a threshold based on the pixel data of pixels that correspond to the same color and the same channel as the target pixel. For instance, the threshold calculator 220 may determine, as the threshold, a value corresponding to the standard deviation of the pixel data of pixels that correspond to the same color and the same channel as the target pixel.

The defective pixel determiner 230 may determine whether the target pixel is a defective pixel based on the threshold (Operation S210). The defective pixel determiner 230 may determine the target pixel to be a defective pixel when a difference between the pixel data of the target pixel and an average of the pixel data of surrounding pixels exceeds the threshold. For example, the defective pixel determiner 230 may determine the target pixel to be a defective pixel when a difference between the pixel data of the target pixel and an average of the pixel data of pixels that correspond to the same color and the same channel as the target pixel exceeds the threshold.

When it is determined that the target pixel is not a defective pixel as a result of determining whether the target pixel is a defective pixel (No in S210), the image signal processor 100 may determine that no separate defective pixel correction is required and may terminate the process.

When it is determined that the target pixel is a defective pixel as a result of determining whether the target pixel is a defective pixel (Yes in S210), the pixel interpolator 330 may interpolate pixel data of the target pixel using the pixel data of pixels included in the target kernel (Operation S220). In one example, the pixel interpolator 330 may interpolate the pixel data of the target pixel based on pixel data of an adjacent pixel neighboring the target pixel, pixel data of pixels having the same attributes as the target pixel, and pixel data of pixels having the same attributes as the adjacent pixel.

The pixel interpolator 330 may interpolate pixel data of the target pixel, and may generate corrected image data (IDATA_P) including the interpolated pixel data of the target pixel.

FIGS. 6 and 7 are diagrams illustrating examples in which operations S130 to S150 shown in FIG. 4 are performed according to an embodiment of the present disclosure.

Referring to FIGS. 1 to 3B and 6, the image signal processor 100 may include an A4C-type sensor. In the present disclosure, the A4C sensor may include a color filter array having a quad-Bayer pattern. A unit pattern of the quad-Bayer pattern may represent a pattern composed of pixels arranged in a (4×4) matrix. Specifically, the unit pattern of the quad-Bayer pattern may be a pattern in which (2×2) matrix-type first pixels having green color filters, (2×2) matrix-type second pixels having red color filters, (2×2) matrix-type third pixels having blue color filters, and (2×2) matrix-type fourth pixels having green color filters are arranged to correspond to the Bayer pattern. For example, the pattern composed of a G00 pixel (G00), a G01 pixel (G01), a G10 pixel (G10), a G11 pixel (G11), an R02 pixel (R02), an R03 pixel (R03), an R12 pixel (R12), an R13 pixel (R13), a B20 pixel (B20), a B21 pixel (B21), a B30 pixel (B30), a B31 pixel (B31), a G22 pixel (G22), a G23 pixel (G23), a G32 pixel (G32), and a G33 pixel (G33) in FIG. 6 may correspond to the unit pattern. Pixels arranged in a (2×2) matrix having color filters of the same color may share a single microlens. Accordingly, the pixels arranged in a (4×4) matrix corresponding to the unit pattern of the quad-Bayer pattern may include four microlenses. The four microlenses included in the unit pattern of the quad-Bayer pattern may be disposed at equal distances from a center point of the unit pattern. For example, one microlens may be disposed at each of the top left, top right, bottom left, and bottom right sides within the unit pattern of the quad-Bayer pattern, such that the four microlenses may be arranged in a (2×2) matrix structure.

The target kernel 600 may include a target pixel corresponding to a green (G) color filter. In the present disclosure, it is assumed that the defective pixel correction operation of the defective pixel corrector 300 is performed in units of a (10×10) kernel having ten rows and ten columns. Each of the columns and rows are designated 0 to 9 with the first number indicating a row and the second number indicating a column. For example, G23 is located in the third row and fourth column of the target kernel 600.

The pixels included in the target kernel 600 may be grouped such that adjacent pixels corresponding to the same color filters are grouped into one pixel group, as shown in the pixel group array 610. For example, the G00 pixel (G00), the G01 pixel (G01), the G10 pixel (G10), and the G11 pixel (G11), which correspond to a green (G) color filter and are adjacent to each other, may be grouped into a GGP00 pixel group (GGP00). For example, the R02 pixel (R02), the R03 pixel (R03), the R12 pixel (R12), and the R13 pixel (R13), which correspond to a red (R) color filter and are adjacent to each other, may be grouped into an RGP01 pixel group (RGP01). For example, the B20 pixel (B20), the B21 pixel (B21), the B30 pixel (B30), and the B31 pixel (B31), which correspond to a blue (B) color filter and are adjacent to each other, may be grouped into a BGP10 pixel group (BGP10). It will be understood that the remaining pixels included in the target kernel 600 may also be grouped in the same manner as described above.

When the G44 pixel (G44), which is the target pixel, is determined to be a defective pixel by the defective pixel determiner 230, the image signal processor 100 may determine a target kernel 600 centered on the GGP22 pixel group (GGP22) corresponding to the pixel group including the G44 pixel (G44). For example, the image signal processor 100 may determine, as the target kernel 600, the smallest rectangular kernel including the G00 pixel (G00), the G09 pixel (G09), the G90 pixel (G90), and the G99 pixel (G99) (corresponding, in this instance, to each of the pixels disposed at the vertices of the smallest rectangular kernel).

When the target kernel 600 is determined to be a pattern kernel by the kernel type determiner 210, and the G44 pixel (G44) serving as the target pixel is determined to be a defective pixel by the defective pixel determiner 230, the pixel data generator 310 may calculate temporary pixel data for the G44 pixel (G44).

In one example, when the target kernel 600 corresponds to a horizontal stripe pattern, the pixel data generator 310 may calculate temporary pixel data by using the pixel data of pixels that are arranged in the left and right directions of the target pixel (G44) and correspond to the same color and the same channel as the target pixel (G44). In this case, the temporary pixel data for the G44 pixel (G44) may satisfy the following equation. In Equation 1 below, TPD may represent temporary pixel data for the G44 pixel (G44), P40 (where P designates temporary or reference pixels within the target kernel 600) may represent pixel data of the G40 pixel (G40), and P48 may represent pixel data of the G48 pixel (G48).

### Equation 1

TPD=(P40+P48)/2

In one example, when the target kernel 600 corresponds to a vertical stripe pattern, the pixel data generator 310 may calculate temporary pixel data by using the pixel data of pixels that are arranged in the vertical direction of the target pixel G44 (G44) and correspond to the same color and the same channel as the G44 pixel (G44). In this case, the temporary pixel data for the G44 pixel (G44) may satisfy the following equation 2. In Equation 2 below, TPD may represent temporary pixel data for the G44 pixel (G44), P04 may represent pixel data of the G04 pixel (G04), and P84 may represent pixel data of the G84 pixel (G84).

### Equation 2

TPD=(P04+P84)/2

In one example, when the target kernel 600 corresponds to a slash-directional pattern, the pixel data generator 310 may calculate temporary pixel data by using the pixel data of pixels that are arranged in the slash direction of the target pixel (G44) and corresponds to the same color and the same channel as the G44 pixel (G44).

In this case, the temporary pixel data for the G44 pixel (G44) may satisfy the following equation 3. In Equation 3 below, TPD may represent temporary pixel data for the G44 pixel (G44), P08 may represent pixel data of the G08 pixel (G08), and P80 may represent pixel data of the G80 pixel (G80).

### Equation 3

TPD=(P08+P80)/2

In one example, when the target kernel 600 corresponds to a backslash-directional pattern, the pixel data generator 310 may calculate temporary pixel data by using the pixel data of pixels that are arranged in the backslash direction of the target pixel (G44) and correspond to the same color and the same channel as the G44 pixel (G44). In this case, the temporary pixel data for the G44 pixel (G44) may satisfy the following equation 4. In Equation 4 below, TPD may represent temporary pixel data for the G44 pixel (G44), and Gmn may represent pixel data of the Gmn pixel (e.g., G00, G88), where ‘m’ and ‘n’ may be integers ranging from 0 to 9.

### Equation 4

TPD=(G00+G88)/2

When temporary pixel data of the target pixel (G44) is determined by the pixel data generator 310, the pixel group determiner 320 may determine a pixel group similar to the GGP22 pixel group (GGP22) serving as the pixel group including the G44 pixel (G44), based on the determined temporary pixel data. For example, the pixel group determiner 320 may determine, among the pixel groups of the pixel group array 610, a pixel group similar to the GGP22 pixel group (GGP22).

The pixel group determiner 320 may calculate a similarity reference score for each pixel group corresponding to the same color filter as that of the GGP22 pixel group (GGP22), and may determine, as the correction pixel group, the pixel group corresponding to the lowest similarity reference score among the calculated scores.

In this case, the similarity reference score for each pixel group may be obtained using the following equations 5 to 16.

In Equations 5 to 16 below, sim_00 to sim_44 represent the similarity reference scores of GGP00 to GGP44 pixel groups, and Gmn represents pixel data of the Gmn pixel, where ‘m’ and ‘n’ are integers ranging from 0 to 9.

### Equation 5

sim_00=abs(TPD−G00)+abs(G45−G01)+abs(G54−G10)+abs(G55−G11)

### Equation 6

sim_02=abs(TPD−G04)+abs(G45−G05)+abs(G54−G14)+abs(G55−G15)

### Equation 7

sim_04=abs(TPD−G08)+abs(G45−G09)+abs(G54−G18)+abs(G55−G19)

### Equation 8

sim_11=abs(TPD−G22)+abs(G45−G23)+abs(G54−G32)+abs(G55−G33)

### Equation 9

sim_13=abs(TPD−G26)+abs(G45−G27)+abs(G54−G36)+abs(G55−G37)

### Equation 10

sim_20=abs(TPD−G40)+abs(G45−G41)+abs(G54−G50)+abs(G55−G51)

### Equation 11

sim_24=abs(TPD−G48)+abs(G45−G49)+abs(G54−G58)+abs(G55−G59)

### Equation 12

sim_31=abs(TPD−G62)+abs(G45−G63)+abs(G54−G72)+abs(G55−G73)

### Equation 13

sim_33=abs(TPD−G66)+abs(G45−G67)+abs(G54−G76)+abs(G55−G77)

### Equation 14

sim_40=abs(TPD−G80)+abs(G45−G81)+abs(G54−G90)+abs(G55−G91)

### Equation 15

sim_42=abs(TPD−G84)+abs(G45−G85)+abs(G54−G94)+abs(G55−G95)

### Equation 16

sim_44=abs(TPD−G88)+abs(G45−G89)+abs(G54−G98)+abs(G55−G99)

The pixel group determiner 320 may determine, as the correction pixel group, the pixel group corresponding to the lowest similarity reference score among the calculated scores.

In this case, a method of determining the correction pixel group based on the similarity reference score may be expressed by the following equation.

In Equation 17 below, sim_00 to sim_44 represent the similarity reference scores of GGP00 to GGP44 pixel groups, min(X) represent a function that derives the pixel group corresponding to the element having the smallest value among the elements of the set X, and min_sad corresponds to the correction pixel group.

### Equation 17

min_sad=min(sim_00, sim_02, sim_04, sim_11, sim_13, sim_20, sim_24, sim_31, sim_33, sim_40, sim_42, sim_44)

In some embodiments, the pixel group determiner 320 may determine a plurality of pixel groups as correction pixel groups. For example, as can be seen from Equation 17, the pixel group determiner 320 may determine multiple pixel groups when there are multiple pixel groups corresponding to elements having the smallest value from among elements of the set X. In this case, the pixel interpolator 330 may interpolate the target pixel using the pixel data of pixels included in each of the plurality of correction pixel groups. In one example, as can be seen from Equation 17, the pixel group determiner 320 may determine the bottom N pixel groups corresponding to elements having the smallest value from among elements of the set X. In this case, the pixel interpolator 330 may interpolate the target pixel using the pixel data of pixels included in each of the plurality of correction pixel groups. Here, N may be a natural number less than or equal to the number of pixel groups.

When the pixel group determiner 320 determines a correction pixel group among the plurality of pixel groups, the pixel interpolator 330 may interpolate the pixel data of the target pixel using the pixel data of pixels included in the correction pixel group. For example, when the pixel group determiner 320 determines the GGP00 pixel group (GGP00) as the correction pixel group, the pixel interpolator 330 may interpolate the pixel data of the target pixel (G44) using pixel data of pixels (G00, G01, G10, G11) included in the GGP00 pixel group (GGP00). For example, when the pixel group determiner 320 determines the GGP00 pixel group (GGP00) as the correction pixel group, the interpolated pixel data of the G44 pixel (G44) may satisfy the following Equation 18. In Equation 18 below, G44 may represent the interpolated pixel data for the G44 pixel (G44), and Gmn may represent the pixel data of the Gmn pixel, where ‘m’ and ‘n’ may be integers ranging from 0 to 9.

### Equation 18

G44=G00+((G45−G01)+(G45−G10)+(G55−G11))/3

The pixel group determiner 320 determines the pixel group most similar to the pixel group including the target pixel and sets the determined pixel group as the correction pixel group, such that the correction performance for defective pixels can be increased even when the target kernel has a complex pattern. For example, even when the target kernel includes both a corner pattern and a stripe pattern, the defective pixel corrector 300 may identify, on a pixel group basis, pixels similar to the target pixel based on the determination result of the pixel group determiner 320. The pixel interpolator 330 may efficiently interpolate the target pixel based on the identified interpolation pixels.

Referring to FIG. 7, pixels included in the target kernel 700 may be grouped such that adjacent pixels corresponding to the same color filter are grouped into pixel groups, as shown in the pixel group array 710. For example, the R00 pixel R00 (R00), the R01 pixel (R01), the R10 pixel (R10), and the R11 pixel (R11), which correspond to a red (R) color filter and are adjacent to each other, may be grouped into an RGP00 pixel group (RGP00). For example, the G02 pixel (G02), the G03 pixel (G03), the G12 pixel (G12), and the G13 pixel (G13), which correspond to a green (G) color filter and are adjacent to each other, may be grouped into a GGP01 pixel group (GGP01). For example, the B22 pixel (B22), the B23 pixel (B23), the B32 pixel (B32), and the B33 pixel (B33), which correspond to a blue (B) color filter and are adjacent to each other, may be grouped as a BGP11 pixel group (BGP11). It will be understood that the remaining pixels included in the target kernel 700 may also be grouped in the same manner as described above.

When the R44 pixel (R44), which is the target pixel, is determined to be a defective pixel by the defective pixel determiner 230, the image signal processor 100 may determine a target kernel 700 centered on the RGP22 pixel group (RGP22), which is the pixel group including the R44 pixel (R44). For example, the image signal processor 100 may determine, as the target kernel 700, the smallest rectangular kernel including the R00 pixel (R00), the R09 pixel (R09), the R90 pixel (R90), and the R99 pixel (R99).

When the target kernel 700 is determined to be a pattern kernel by the kernel type determiner 210, and the target pixel R44 (R44) is determined to be a defective pixel by the defective pixel determiner 230, the pixel data generator 310 may calculate temporary pixel data for the R44 pixel (R44).

Referring also to FIG. 6, the target kernel 600 of FIG. 6 may correspond to a kernel that is set when the target pixel corresponds to a green (G) color filter, and the target kernel 700 of FIG. 7 may correspond to a kernel that is set when the target pixel corresponds to a red (R) color filter. A method of interpolating the pixel data of the target pixel R44 (R44) may be understood in the same manner as the method described above with reference to FIG. 6.

For example, the pixel group determiner 320 may determine a pixel group similar to the RGP22 pixel group (RGP22) including the target pixel (R44) from among the RGP00 pixel group (RGP00), the RGP02 pixel group (RGP02), the RGP04 pixel group (RGP04), the RGP20 pixel group (RGP20), the RGP24 pixel group (RGP24), the RGP40 pixel group (RGP40), the RGP42 pixel group (RGP42), and the RGP44 pixel group (RGP44).

The pixel group determiner 320 may calculate similarity reference scores of pixel groups that are candidate correction pixel groups and correspond to the same color filter as the color filter corresponding to the RGP22 pixel group (RGP22). Even when the target pixel corresponds to a blue (B) color filter, the same concepts and operations may be performed in the same manner as the above-described method.

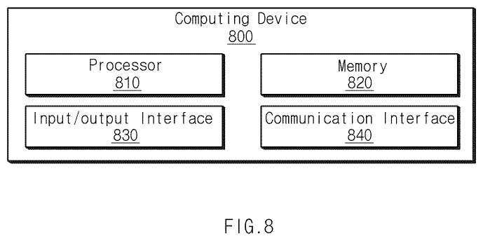

FIG. 8 is a block diagram illustrating an example of a computing device 800 corresponding to the image signal processor of FIG. 1.

Referring to FIG. 8, the computing device 800 may represent an embodiment of a hardware configuration for performing the operation of the image signal processor 100 of FIG. 1.

The computing device 800 may be mounted on a chip that is independent from the chip on which the image sensing device is mounted. According to one embodiment, the chip on which the image sensing device is mounted and the chip on which the computing device 800 is mounted may be implemented in one package, for example, a multi-chip package (MCP), but the scope of the present disclosure is not limited thereto.

Additionally, the internal configuration or arrangement of the computing device 800 and the image sensing device may vary depending on the embodiment. For example, at least a portion of the image sensing device may be included in the computing device 800. Alternatively, at least a portion of the computing device 800 may be included in the image sensing device. In this case, at least a portion of the computing device 800 may be mounted together on a chip on which the image sensing device is mounted.

The computing device 800 may include a processor 810, a memory 820, an input and output (input/output) (I/O) interface 830, and a communication interface 840.

The processor 810 may process data and/or instructions required to perform the operations of the components of the image signal processor 100 described in FIG. 1. That is, the processor 810 may refer to the image signal processor 100, but the scope of the present disclosure is not limited thereto.

The memory 820 may store data and/or instructions required to perform operations of the components 200 and 300 of the image signal processor 100, and may be accessed by the processor 810. For example, the memory 820 may be volatile memory (e.g., Dynamic Random Access Memory (DRAM), Static Random Access Memory (SRAM), etc.) or non-volatile memory (e.g., Programmable Read Only Memory (PROM), Erasable PROM (EPROM), Electrically Erasable PROM (EEPROM), flash memory, etc.).

That is, the computer program for performing the operations of the image signal processor 100 described in the present disclosure may be recorded in the memory 820 and executed and processed by the processor 810, thereby implementing the operations of the image signal processor 100.

The input/output (I/O) interface 830 is an interface that connects an external input device (e.g., keyboard, mouse, touch panel, etc.) and/or an external output device (e.g., display) to the processor 810 to allow data to be transmitted and received.

The communication interface 840 is a component capable of transmitting and receiving various data to and from an external device (e.g., an application processor, external memory, etc.), and may be a device that supports wired or wireless communication.

As is apparent from the above description, the image signal processor and the image signal processing method according to the embodiments of the present disclosure may determine the directionality of a target kernel in consideration of characteristics of the sensor using a microlens, and may interpolate the target pixel based on the determined directionality, so that the embodiments provide a capability to improve the accuracy of defective pixel correction even when errors occur between pixels due to a phase difference.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. An image signal processor comprising:
a pixel data generator configured to generate first data by using pixel data of each of pixels having same attributes as a target pixel included in a target kernel from among a plurality of pixels included in the target kernel;
a pixel group determiner configured to determine a correction pixel group from among a plurality of pixel groups included in the target kernel by using the first data; and
a pixel interpolator configured to determine second data based on pixel data of pixels included in a pixel group including the target pixel and pixel data of pixels included in the correction pixel group, and to determine pixel data of the target pixel based on the second data.

2. The image signal processor according to claim 1, wherein:
each of the pixels having the same attributes as the target pixel has a color filter of a same color as that of a color filter corresponding to the target pixel, and is located in a same channel as the target pixel.

3. The image signal processor according to claim 2, wherein the pixel data generator is configured to:
generate the first data using pixel data of one or more pixels that have the same attributes as the target pixel and are located on a line in one direction from the target pixel.

4. The image signal processor according to claim 2, wherein the pixel group determiner is configured to:
determine the correction pixel group based on a comparison result between pixel data of an adjacent pixel neighboring the target pixel and pixel data of pixels having same attributes as the adjacent pixel from among pixels included in the plurality of pixel groups.

5. The image signal processor according to claim 4, wherein:
the adjacent pixel includes a pixel that shares a microlens with the target pixel.

6. The image signal processor according to claim 2, wherein the pixel interpolator is configured to:
calculate the second data based on a comparison result between pixel data of an adjacent pixel neighboring the target pixel and pixel data of pixels having same attributes as the adjacent pixel from among pixels included in the correction pixel group.

7. The image signal processor according to claim 1, wherein:
the target kernel has a quad-Bayer pattern.

8. The image signal processor according to claim 7, wherein:
pixels corresponding to a unit pattern of the quad-Bayer pattern include four microlenses.

9. The image signal processor according to claim 1, further comprising:
a flat kernel determiner configured to determine whether the target kernel is a flat kernel based on a standard deviation of pixel data of each pixel included in the target kernel.

10. The image signal processor according to claim 9, wherein the pixel interpolator is configured to:
when it is determined that the target kernel is the flat kernel, determine the pixel data of the target pixel to be a value corresponding to an average of pixel data of pixels having the same attributes as the target pixel.

11. An image signal processor comprising:
a pattern kernel determiner configured to determine whether a target kernel is a pattern kernel;
a defective pixel determiner configured to determine whether a target pixel included in the target kernel is a defective pixel when it is determined that the target kernel is the pattern kernel;
a pixel data generator configured to generate first data by using pixel data of pixels having same attributes as the target pixel when it is determined that the target pixel is the defective pixel;
a pixel group determiner configured to determine a correction pixel group from among a plurality of pixel groups included in the target kernel by using the first data; and
a pixel interpolator configured to determine second data based on pixel data of pixels included in a target pixel group including the target pixel and pixel data of pixels included in the correction pixel group, and to determine data of the target pixel based on the second data.

12. The image signal processor according to claim 11, wherein the pattern kernel determiner is configured to:
determine the target kernel to be a pattern kernel when a standard deviation of pixel data of each pixel included in the target kernel is greater than or equal to a set value.

13. The image signal processor according to claim 11, wherein:
the same attributes include a color filter and a channel.

14. The image signal processor according to claim 13, wherein the defective pixel determiner is configured to:
determine the target pixel to be a defective pixel when a difference between pixel data of the target pixel and an average of pixel data of pixels having the same attributes as the target pixel is greater than or equal to a threshold.

15. The image signal processor according to claim 11, wherein the pixel data generator is configured to:
generate the first data using pixel data of one or more pixels that have the same attributes as the target pixel and are located on a line in one direction from the target pixel.

16. The image signal processor according to claim 11, wherein the pixel group determiner is configured to:
determine the correction pixel group based on a comparison result between pixel data of an adjacent pixel neighboring the target pixel and pixel data of pixels having same attributes as the adjacent pixel from among pixels included in the plurality of pixel groups.

17. The image signal processor according to claim 11, wherein the pixel interpolator is configured to:
calculate the second data based on a comparison result between pixel data of an adjacent pixel neighboring the target pixel and pixel data of pixels having same attributes as the adjacent pixel from among pixels included in the correction pixel group.

18. An image signal processing method comprising:
determining whether a target kernel including a target pixel is a pattern kernel;
determining whether the target pixel is a defective pixel;
generating first data by using pixel data of pixels having same attributes as the target pixel included in the target kernel;
determining a correction pixel group from among a plurality of pixel groups included in the target kernel by using the first data;
determining second data based on pixel data of pixels included in a target pixel group including the target pixel and pixel data of pixels included in the correction pixel group; and
determining data of the target pixel based on the second data.

19. The image signal processing method according to claim 18, wherein the determining the correction pixel group includes:
determining the correction pixel group based on a comparison result between pixel data of an adjacent pixel neighboring the target pixel and pixel data of pixels having same attributes as the adjacent pixel from among pixels included in the plurality of pixel groups.

20. The image signal processing method according to claim 18, wherein the determining the data of the target pixel based on the second data includes:
determining the second data based on a comparison result between pixel data of an adjacent pixel neighboring the target pixel and pixel data of pixels having same attributes as the adjacent pixel from among pixels included in the correction pixel group.
